(19) United States
(12) Patent Application Publication
(10) Pub. No.: US 2007/0229200 A1
(43) Pub. Date: Oct. 4, 2007

(54) Attenuator

(75) Inventors: Tse-Lun Lee, Taipei Hsien (TW); Sen-Lu Wang, Taipei Hsien (TW); Steven Yang, Taipei Hsien (TW)

Correspondence Address: BACON & THOMAS, PLLC, 625 SLATERS LANE, FOURTH FLOOR, ALEXANDRIA, VA, 22314, US

(73) Assignee: MICON PRECISE CORPORATION, Taipei Hsien (TW)

(21) Appl. No.: 11/448,896

(22) Filed: Jun. 8, 2006

(30) Foreign Application Priority Data
Apr. 4, 2006 (TW) 095205642

(51) Int. Cl. H01P 1/22; H03H 7/24

(52) U.S. Cl. 333/81 A

(57) ABSTRACT

An attenuator includes a main body and a circuit board module, wherein the main body is made of an electrically conducting metal, and an installing portion is concavely disposed between both ends of the main body, and a portion of the circuit board module is disposed on the installing portion for reducing the contact area between the circuit board module and the main body, so as to lower the parasite capacitance of the attenuator between the circuit board module and the main body, and the circuit board module processes a signal introduced by the main body according to a predetermined attenuation.

### FIELD OF THE INVENTION

The present invention relates to an attenuator, and more particularly to an attenuator capable of reducing the contact area between a main body and a circuit board module of the attenuator to lower the parasite capacitance of the attenuator between the circuit board module and the main body.

### BACKGROUND OF THE INVENTION

In general, an attenuator is usually used in various different telecommunication equipments and electronic instruments for introducing a circuit with a predetermined attenuation within a specific frequency range, and thus the attenuator is labeled by its introduced attenuation decibel (dB) and impedance in ohm. In a testing mode, the attenuators are extensively used for satisfying the power potential requirements of each port such as the potential control of an input end or an output end of an amplifier or a receiver.

Further, the frequency of an attenuator needs to satisfy the frequency range requirements of a system or a testing, and the attenuation is not related to the frequency within a frequency range of the attenuator, and thus an attenuator is usually made of a resistive material and different frequency ranges, and attenuators come in different types such as an attenuator made of an in-line cable, an attenuator used as a diaphragm in a microwave and a radio frequency system for absorbing the energy of an electric field, and an attenuator that employs a solid-state diode (such as a PIN diode) to make a microwave or an in-line system within a microwave frequency for harmonizing potentials.

Most circuits of a traditional microwave or radio frequency attenuator adopt a thin film technology or a thick film technology and a vacuum spluttering method plus lithography and etching processes or a screen printing plus a high-temperature baking method to form a resistive material and an electric conducting material on a substrate made of aluminum oxide or ceramic materials, such that the substrate has a resistor network with a low reactance, and a cut and shaped substrate is installed in the structure at both ends of the in-line connector to form an in-line attenuator, and the resistor network of the in-line attenuator is usually Pi-shaped, T-shaped, or distributed, and its applicable frequency could be over 18 GHz ( refer to Stephen F. Adam, Microwave Theory and Applications, Prentice-Hall, Inc, 1969, p 353-357). A discrete chip resistor is fixed onto a circuit board having microstrips by technologies including soldering or electrically conducting glue adhesion to form a Pi-shape or T-shape network attenuator, so as to extend the operating frequency to 4 GHz (as disclosed in U.S. Pat. No. 6,903,621), and the chip resistor and the circuit board can be obtained easily and their manufacture is easy for producing a cost-effective microwave attenuator. As to the microwave attenuator made of chip resistors for a Pi-shape network circuit, its simplified equivalent circuit as shown in FIG. 1 adheres a plurality of discrete chip resistors 21, 22, 23 to a circuit board to form a Pi-shape circuit board, and the Pi-shape circuit board is installed between both ends of a metal enclosure of an in-line connector, so as to constitute the microwave attenuator. Due to the high-frequency properties of the circuit board, the skin effect of the resistor, the parasite inductance, the parasite capacitance, and the soldering point, the frequency response and the standing wave ratio of the microwave attenuator are limited.

Referring to FIGS. 1 and 2, the circuit board includes a plurality of solder pads 30-1, 30-2, 31-1, 31-2, 32-1, 32-2, 33-1, 33-2, wherein a first resistor 21 is disposed between the solder pad 31-1 and the solder pad 31-2; a second resistor 22 is disposed between the solder pad 32-1 and the solder pad 32-2; a third resistor 23 is disposed between the solder pad 33-1 and the solder pad 33-2; the first resistor 21 and the third resistor 23 are Pi-shape network shunt branch resistors, and the second resistor 22 is a serial branch resistor; and an in-line terminal inside the metal enclosure is connected to the circuit board (in other words, an in-line structure is converted to a planar circuit) to produce parasite capacitances C1, C2, and a parasite capacitance C3 is produced between the solder pad 31-1, the solder pad 31-2 and the ground surface, a parasite capacitance C4 is produced between the solder pad 33-1, the solder pad 33-2 and the ground surface, and a parasite capacitance C5 is produced between the solder pad 32-1, the solder pad 32-2 and second resistor 22.

Referring to FIG. 1, the parasite capacitances C3˜C5 are produced between the parasite capacitances C1, C2 and the solder pads 31-1, 31-2, 32-1, 32-2, 33-1, 33-2. Referring to FIG. 2, the influences of the parasite reactance Cr, Lr1, Lr2 of the chip resistors and the parasite capacitances and inductance on the attenuator will be increased as the frequency increases. Obviously, the deviation and the standing wave ratio (also known as return loss) of the attenuation are deteriorated. For example, if the feature of the design target value of the attenuator is a straight line 60, but generally the feature of three chip resistors being combined into a Pi-shape attenuator at a low attenuation (such as 1 dB, 2 dB, . . . , 7 dB) is similar to a curve 61 which rolls down with the frequency and primarily affected by the parasite capacitances C1˜C4. Further, the feature of the high attenuation (such as 20 dB and 30 dB) of the Pi-shape attenuator is similar to a curve 62 which rolls up with the frequency and primarily affected by the parasite reactance and the parasite capacitance C5 of the second resistor 22.

Therefore, finding a way of reducing the effect of parasite capacitances C1˜C5 at a high frequency produced by connecting the in-line terminal to the circuit board and the chip resistor, such that the standing wave ratio of the attenuator will not be deteriorated when the frequency rolls up, and the difference between the attenuation and the target value will not increase as the frequency rolls up is an issue that requires immediate attention and feasible solutions.

### SUMMARY OF THE INVENTION

In view of the shortcomings of the prior art, the inventor of the present invention based on years of experience to conduct extensive researches and experiments, and finally designed and developed an attenuator in accordance with the present invention to overcome the shortcomings of the prior art.

Therefore, it is a primary objective of the present invention to provide an attenuator comprising a main body and a circuit board module, wherein the main body includes an installing portion concavely disposed between both ends of the main body, and a portion of the circuit board module is disposed on the installing portion to reduce the contact area between the circuit board module and the main body, so as to lower a parasite capacitance of the attenuator between the circuit board module and the main body, and the circuit board module processes a signal introduced by the main body according to a predetermined attenuation.

### BRIEF DESCRIPTION OF THE DRAWINGS

FIG. 1 is a schematic view of a Pi network equivalent circuit;

FIG. 2 is a circuit diagram of a resistor equivalent circuit of a chip as depicted in FIG. 1;

FIG. 3 is schematic view of properties as depicted in FIG. 1;

FIG. 4 is a schematic view of a main body, a circuit board module and a casing of the present invention;

FIG. 5 is a schematic view of a main body and a circuit board module of the present invention;

FIG. 6 is a cross-sectional view of the present invention;

FIG. 7 is a circuit board module before installing resistors for 8 dB, 9 dB and 10 dB attenuators according to the present invention;

FIG. 8 is a circuit board module after installing resistors for 8 dB, 9 dB and 10 dB attenuators according to the present invention;

FIG. 9 is a circuit board module before installing resistors for 1 dB, 2 dB . . . 7 dB attenuators according to the present invention;

FIG. 10 is a circuit board module after installing resistors for 1 dB, 2 dB . . . 7 dB attenuators according to the present invention;

FIG. 11 is a circuit board module before installing resistors for 20 dB and 30 dB attenuators according to the present invention;

FIG. 12 is a schematic view of a circuit board module after installing resistors for 20 dB and 30 dB attenuators according to the present invention;

FIG. 13 is a schematic view of testing properties of a 1 dB attenuator;

FIG. 14 is a schematic view of testing properties of a 3 dB attenuator;

FIG. 15 is a schematic view of testing properties of a 6 dB attenuator;

FIG. 16 is a schematic view of testing properties of a 10 dB attenuator;

FIG. 17 is a schematic view of testing properties of a 20 dB attenuator; and

FIG. 18 is a schematic view of testing properties of a 30 dB attenuator.

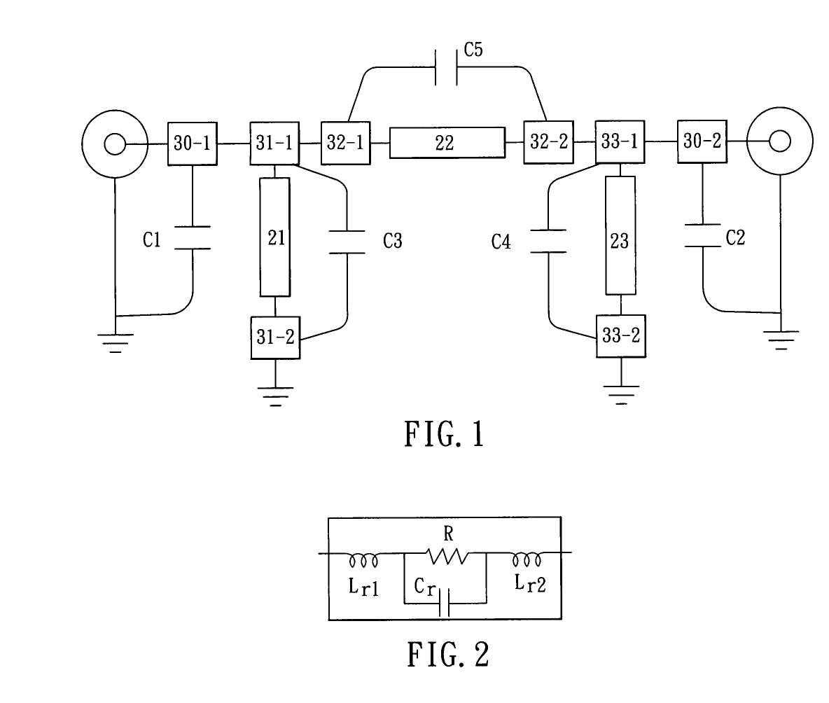

### DETAILED DESCRIPTION OF THE PREFERRED EMBODIMENTS

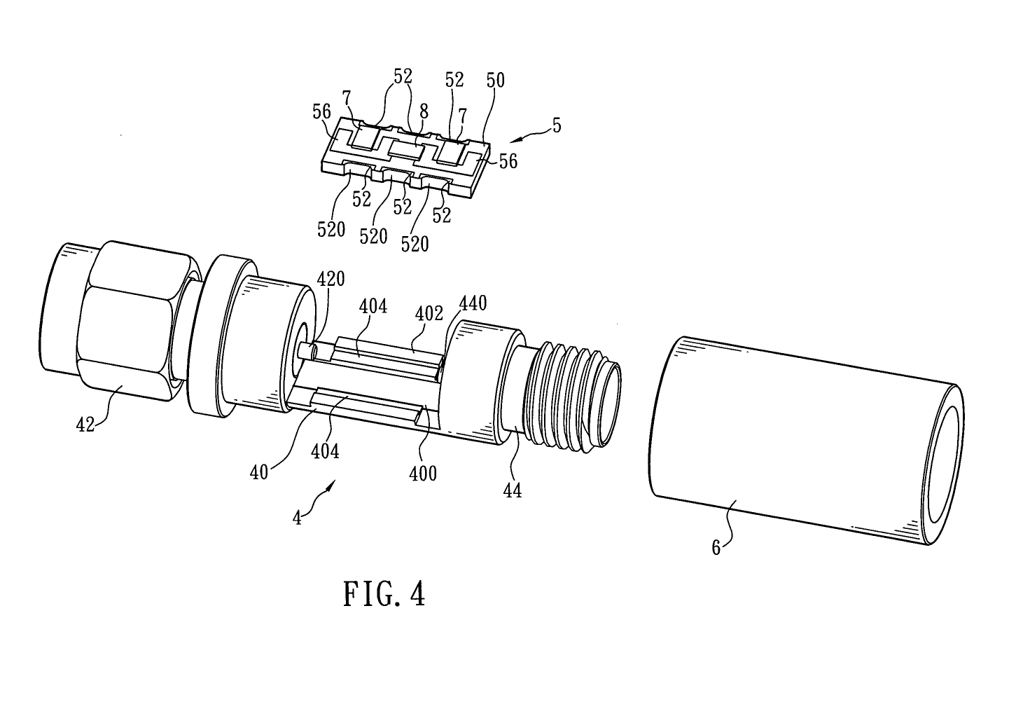

Referring to FIG. 4 for the attenuator of the present invention, the attenuator comprises a main body 4 and a circuit board module 5, wherein the main body 4 is made of an electrically conducting metal, and an installing portion 40 is concavely disposed between both ends of the main body 4, and a portion of the circuit board module 5 is disposed on the installing portion 40 for reducing the contact area between the circuit board module 5 and the main body 4, so as to lower the parasite capacitance of the attenuator between the circuit board module 5 and the main body 4, and the circuit board module 5 processes a signal introduced by the main body 4 according to a predetermined attenuation.

In a preferred embodiment of the present invention, a first connecting portion 42 such as a male plug is disposed between an end of the main body 4 and the installing portion 40, and the first connecting portion 42 includes a first central conductor 420 disposed at a position facing the installing portion 40, and the first central conductor 420 is coupled precisely to the circuit board module 5 and disposed at a position proximate to the first connecting portion 42, and a second connecting portion 44 such as a female jack is disposed between another end of the main body 4 and the second installing portion 40, and the second connecting portion 44 includes a second central conductor 440 facing the installing portion 40, and the second central conductor 440 is coupled to the circuit board module 5 and disposed at a position proximate to the second connecting portion 44, such that after the connecting portion 42 is connected to a signal line, the signal transmitted by the signal line passes through the first central conductor 420 into the circuit board module 5 for the attenuation processing, and then passes through the second central conductor 440 and the second connecting portion 44 to another signal line connected to the second connecting portion 44.

In the preferred embodiment, the installing portion 40 at its central position includes a groove 400, and the installing portion 40 includes a protruding body 402 disposed separately on both sides of the groove 400, and the protruding body 402 includes a shoulder portion 404 separately disposed adjacent to the groove 400, and the shoulder portions 404 are precisely in contact with the positions on both sides of the circuit board module 5 and proximate to the bottom of the circuit board module 5 and the bottom of the circuit board module 5 and proximate to both sides of the circuit board module 5, and the position of the bottom of the circuit board module 5 facing the groove 400 is not in contact with the main body 4, so that the circuit board module 5 is installed and limited to the installing portion 40. By reducing the contact surface between the circuit board module 5 and the main body 4, the capacitance of the parasite capacitors of the circuit board module 5 can be reduced.

In the preferred embodiment, the main body 4 includes a casing 6 disposed around the periphery of the installing portion 40, such that after the casing 6 is connected to the main body 4, the casing 6 can protect and prevent the circuit board module 5 from being affected by electromagnetic interference. The connecting portion 42 and another connecting portion 44 are connectors in the shape and specification of SMA, N, TNC, and BNC, etc.

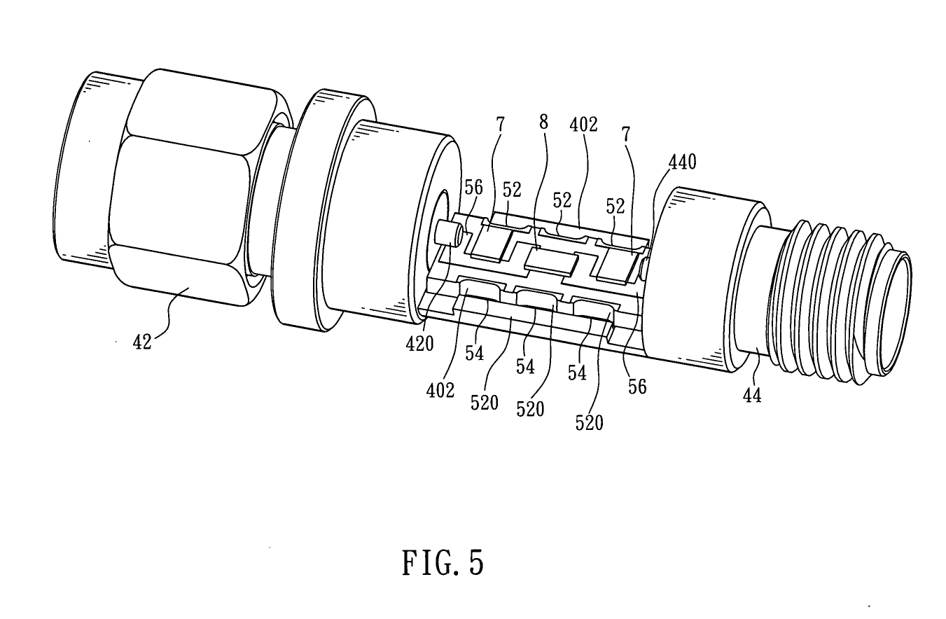

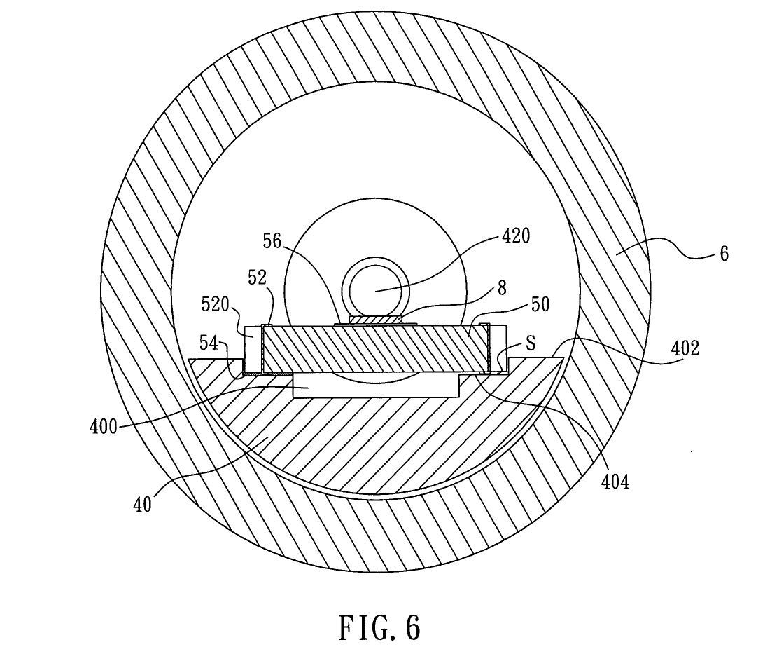

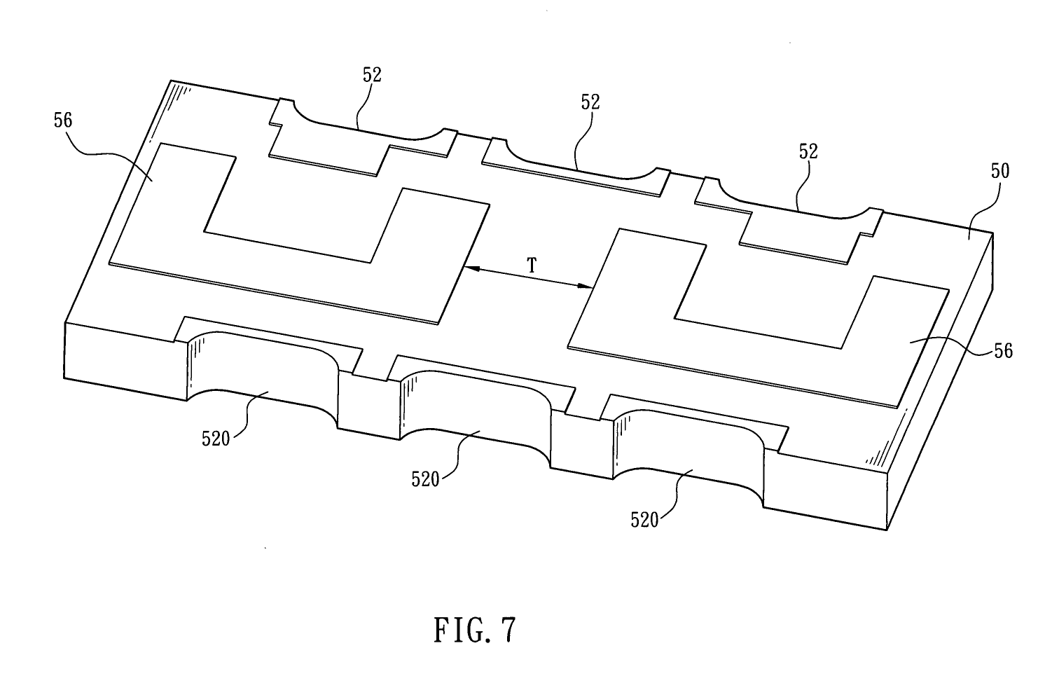

In the preferred embodiment as shown in FIGS. 5 and 6, the circuit board module 5 includes a circuit board 50, and the circuit board module 5 includes a plurality of first solder pads 52 intervally disposed on both sides of the circuit board 50 facing the protruding body 402 and extended to the center of both surfaces of the circuit board module 5, and a connecting layer 54 (such as a solder or an electrically conducting glue) is disposed between the first solder pad 52 and the protruding body 402 for fixing the circuit board module 5 at the installing portion 40.

To securely install the circuit board module 5 to the installing portion 40, the first solder pad 52 of the preferred embodiment includes a groove 520 disposed at a position facing the protruding body 402, such that after the circuit board module 5 is installed onto the installing portion 40, a gap S is formed between the groove 520 and the protruding body 402, and the connecting layer 54 is disposed in the gap S, so as to facilitate the grounding of signals and the heat dissipation of the circuit board module 5.

In the preferred embodiment, the circuit board 50 includes a plurality of second solder pads 56 between the opposite side of the groove 400 and the first solder pads 52, and the second solder pads 56 include at least one first resistor 7 (such as a discrete chip resistor) separated disposed between at least one side of the circuit board module 5 and a first solder pad 52, and the first resistor 7 forms a Pi-shape network shunt branch resistor, and at least one second resistor 8 disposed between the second solder pads 56, and the second resistors 8 form a Pi-shape network serial branch resistor.

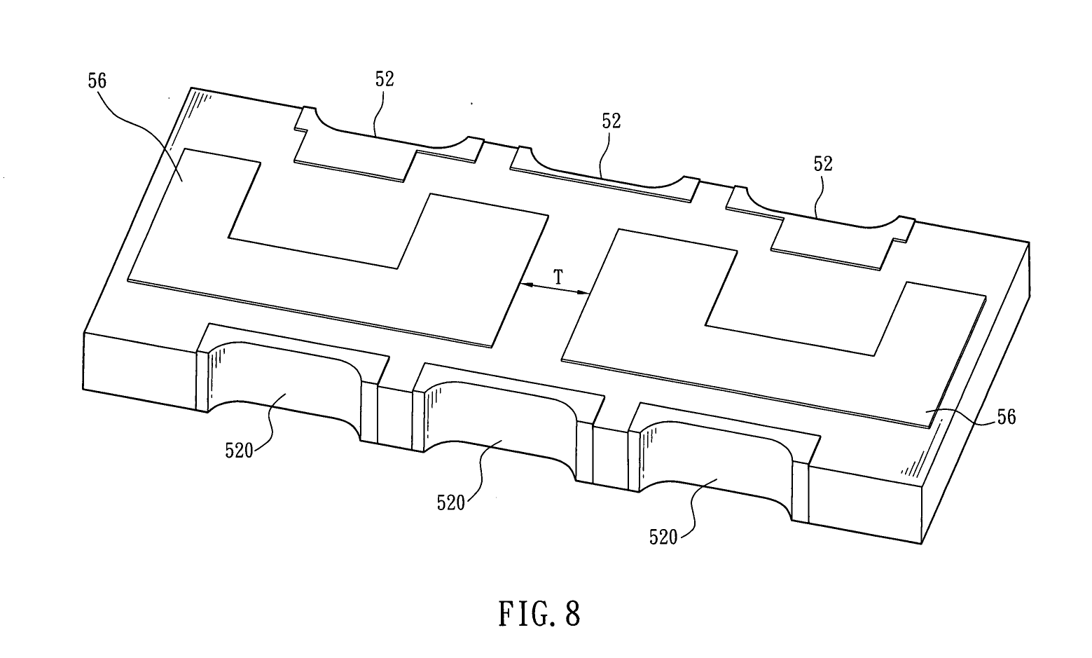

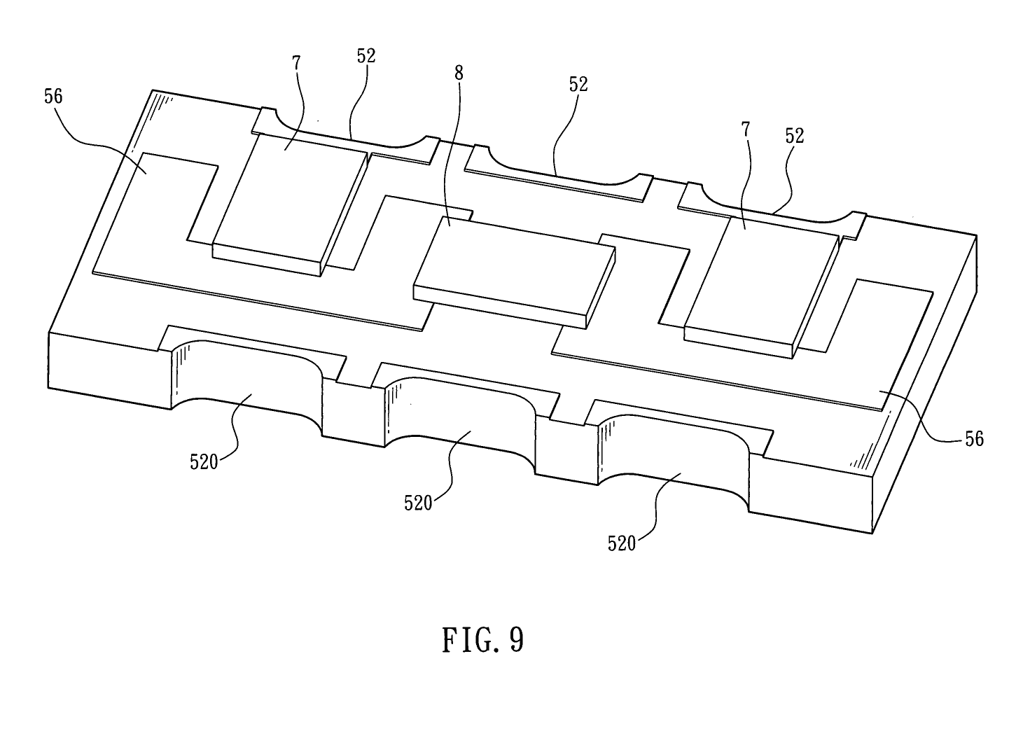

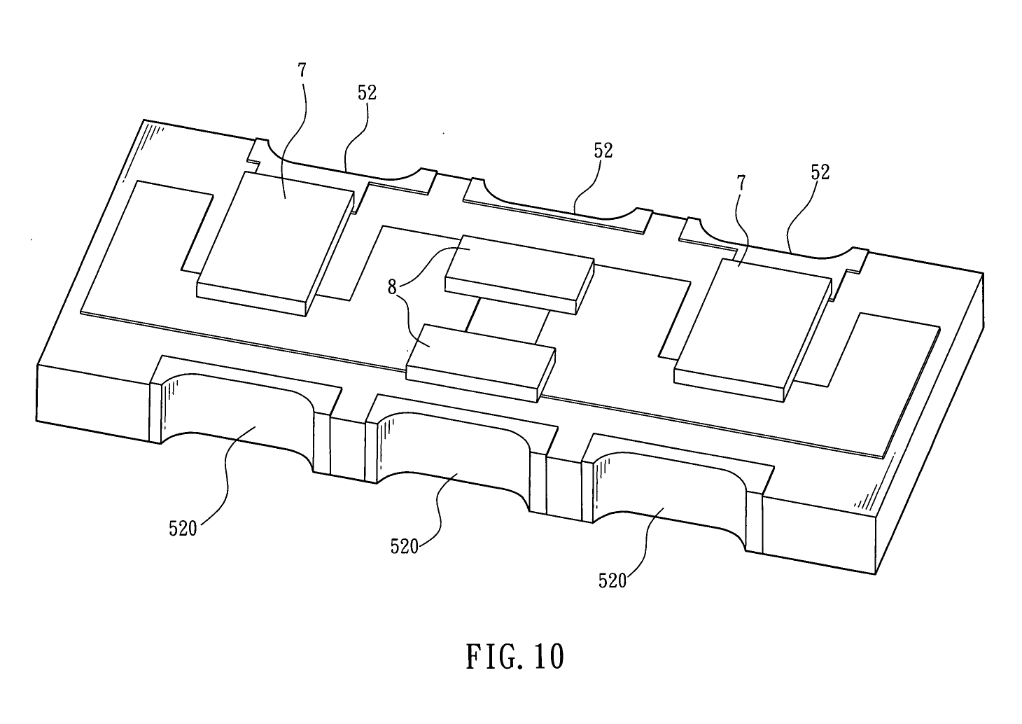

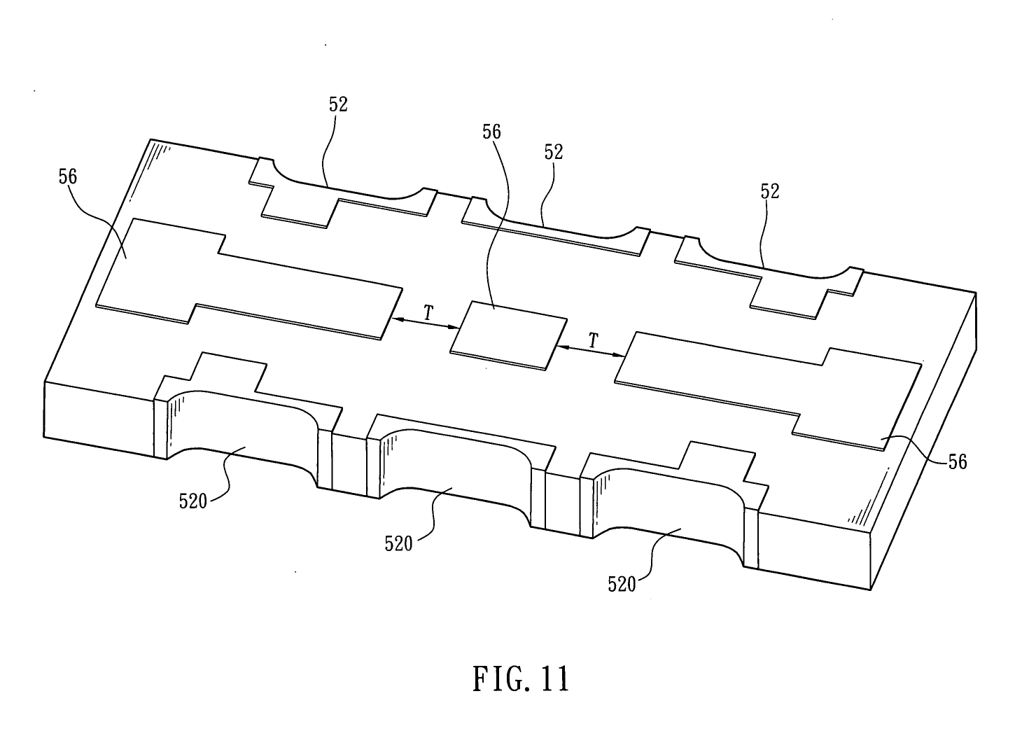

In the preferred embodiment as shown in FIGS. 7 and 8, the circuit board 50 includes two second solder pads 56 which are substantially U-shaped, and an indent of the second solder pads 56 faces the same lateral side of the circuit board 50, and the second resistors 8 are installed on the same corresponding lateral side of the second solder pads 56 (as shown in FIGS. 9 and 10), and the central conductor 420 is installed on the opposite side of the second solder pads 56. Further, both sides of the circuit board 50 include three first solder pads 52 (as shown in FIGS. 7 and 8), wherein two of the first solder pads 52 precisely correspond to the indent of the second solder pads 56 and installed between the indent facing the second solder pads 56 of the first solder pad 52 and the second solder pad 56 (as shown in FIGS. 9 and 10), and another one of the first solder pads 52 corresponds to a gap T between two second solder pads 56.

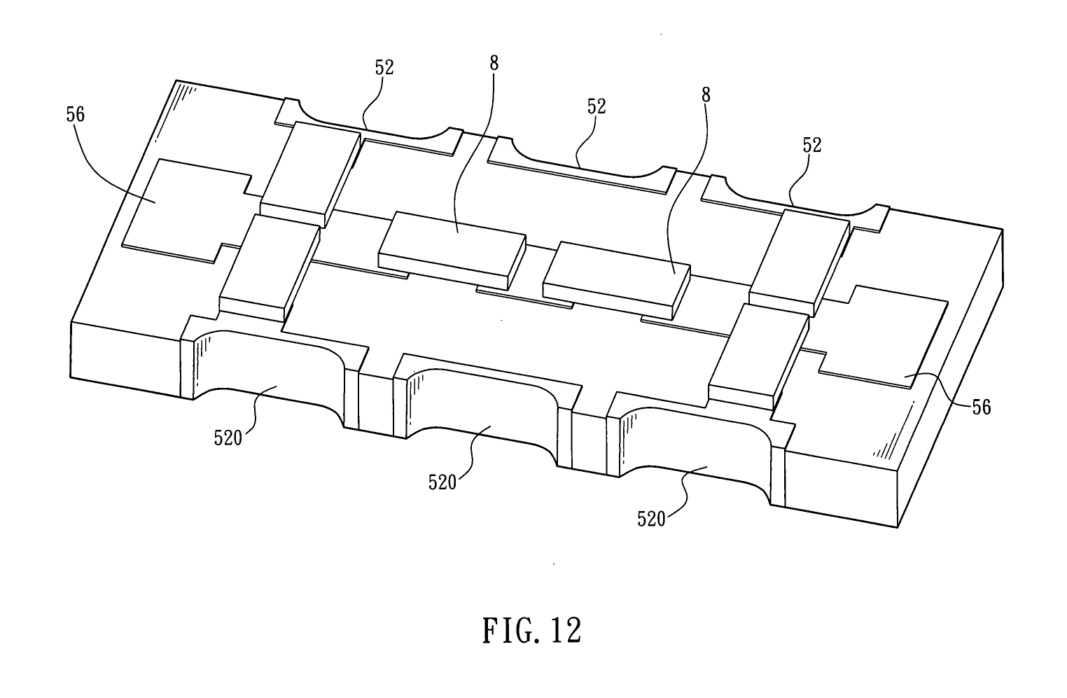

In the preferred embodiment as shown in FIGS. 11 and 12, the circuit board 50 includes two T-shape second solder pads 56 and a rectangular second solder pad 56 disposed between the two T-shape second solder pads 56, and the second resistors 8 are installed on the same corresponding side of the rectangular second solder pad 56 and the T-shape second solder pads 56, and the central conductor 420 is installed precisely on the opposite side of the T-shape second solder pads. Further, both sides of the circuit board 50 include three first solder pads 52, wherein two of the first solder pads 52 precisely correspond to the T-shape second solder pad 56 and is disposed proximate to the rectangular second solder pad 56, and another one of the first solder pads 52 correspond to the rectangular second solder pads 56, and the first resistors 7 are installed between a lateral side of the T-shape second solder pad 56 proximate to the rectangular second solder pad 56 and a lateral side of the first solder pad 52 and the T-shape second solder pad 56 proximate to the rectangular second solder pad 56. It is worthy pointing out that the first solder pad 52 of the resistor 7 disposed on the circuit board 50 and not connected to the second solder pad 56 is not a necessary component with the functions of reinforcing the strength between the circuit board 50 and the main body 4, improving the signal grounding and heat dissipating efficiency, and reducing the capacitance of the parasite capacitors.

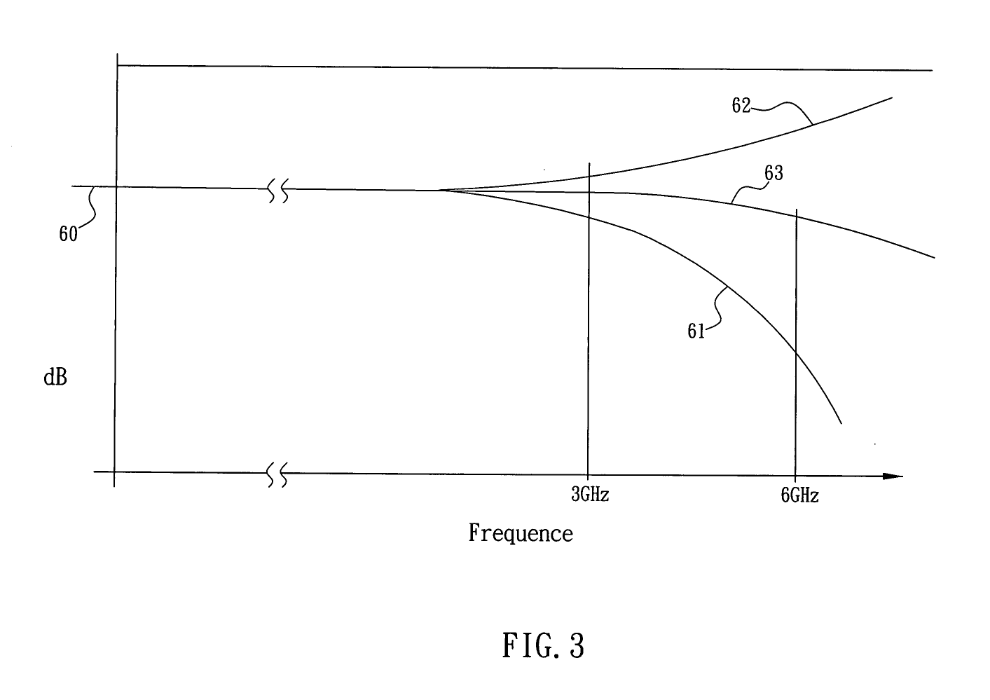

From the description above, the structural design of the main body 4 and the layout of the circuit board 50 and the resistor 7, 8 can effectively control and use the parasite capacitance between the conductors of the circuit board 50. Some parasite reactance offset with each other or serve for the compensation function, so that the attenuator can maintain its properties and the advantages of having good attenuation return loss (or standing wave ratio), attenuation precision, and frequency response flatness; particularly when the attenuator of 1 dB to 30 dB in accordance with the structure of the present invention operates at 6 GHz, its frequency response can improve the similar curve 63, so that it approaches the target value as shown in FIG. 3, and the standing wave ratio is less than 1.30:1 (approximately equals to the return loss which is superior than 17.7 dB). The circuit board 50 does not require a transmission line or a special microwave board, but a traditional board (such as FR4) can serve the same purpose, and the resistors are the chip resistors of the series of 0805 and 0603 of the general industrial standard and specification.

Referring to FIG. 9 for the schematic view of the circuit board module 5 of the 8 dB, 9 dB and 10 dB attenuators of the invention, the first resistors 7 are shunt branch resistors, and the second resistor 8 is a serial branch resistor, and the resistors 7, 8 are chip resistors of the 0805 specification. Referring to FIG. 10 for the schematic view of a circuit board module 5 of the 1 dB, 2 dB . . . 7 dB attenuators of the present invention, the first resistor 7 is a shunt branch resistor which is a chip resistor of the 0805 specification, and the second resistor 8 is connected in parallel between two second solder pads 56 and serves as a serial branch resistor which is a chip resistor of the 0603 specification, and the interval T between two second solder pad 56 is smaller than that for the chip resistor of the 0805 specification, and the second resistors 8 are installed separately at the positions of the two second solder pads 56 proximate to both lateral sides of the circuit board. Such arrangement copes with the features of the current distribution at the external side of the attenuator to increase the capacitance of the parasite capacitor C5 of the serial branch resistor to improve the compensation effect.

Referring to FIG. 12 for the schematic view of a circuit board module 5 of the 20 dB and 30 dB attenuators of the present invention, the first resistor 7 is connected in parallel between the first solder pad 52 and the second solder pad 56 as a shunt branch resistor, and the second resistor 8 is connected in series between the T-shape second solder pad and the rectangular solder pad 56. The resistors 7, 8 are chip resistors with the 0603 specification for reducing the parasite capacitance, and the connections in parallel and in series can improve the power rating.

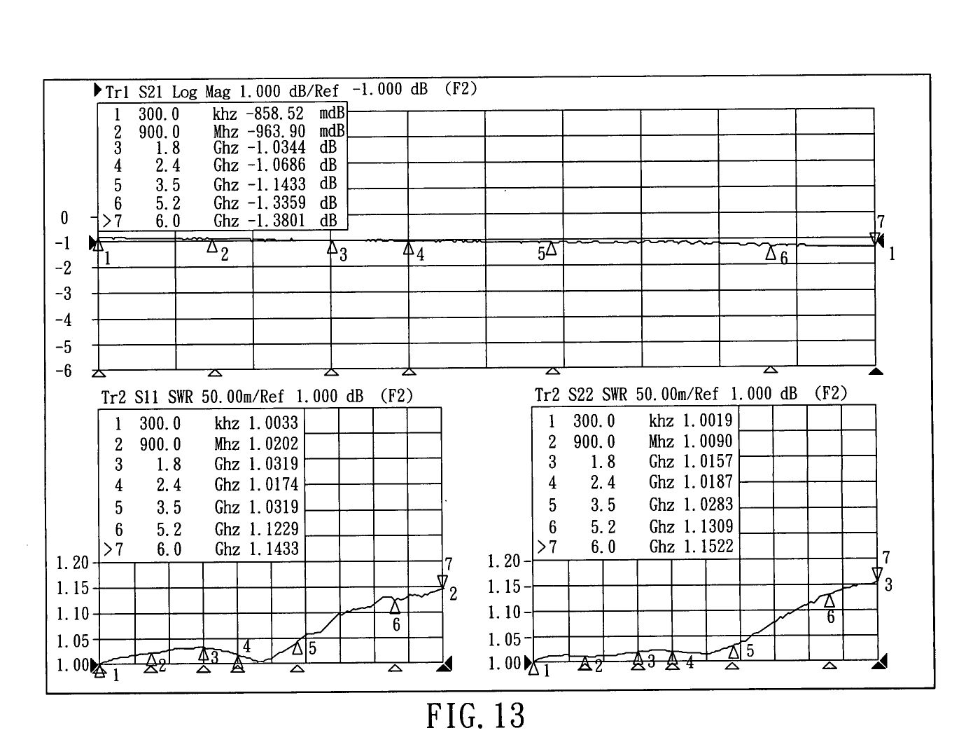

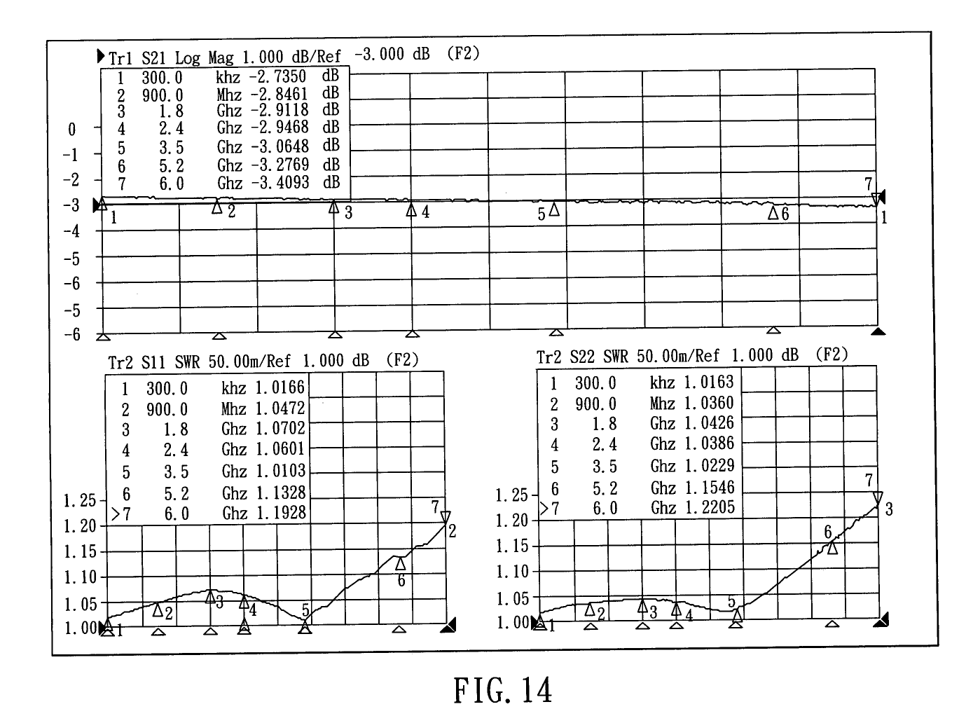

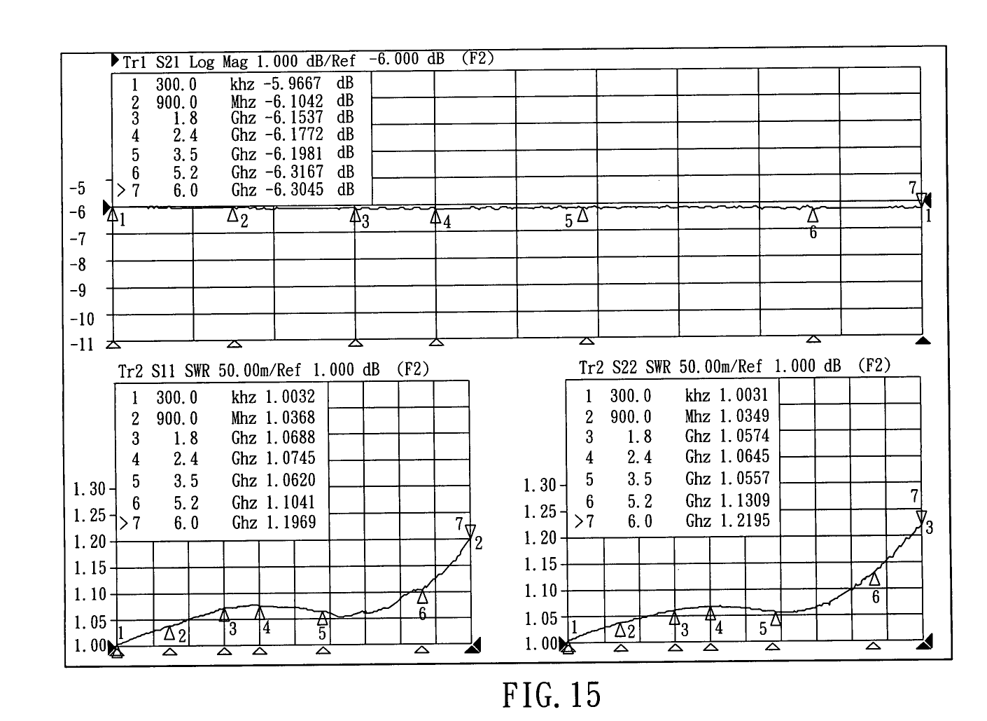

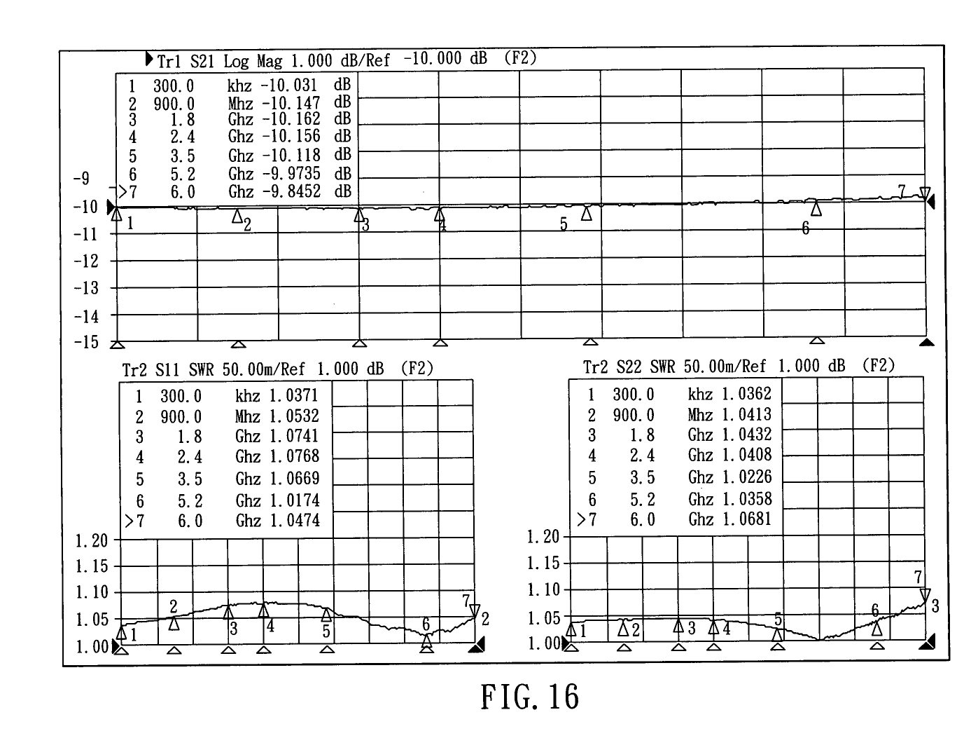

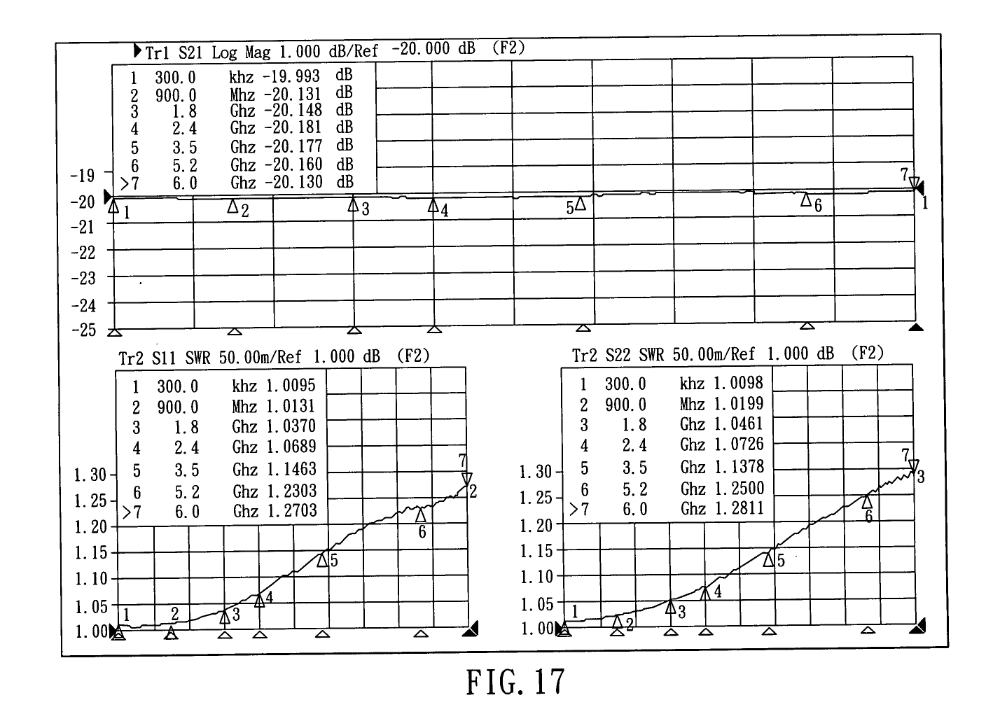

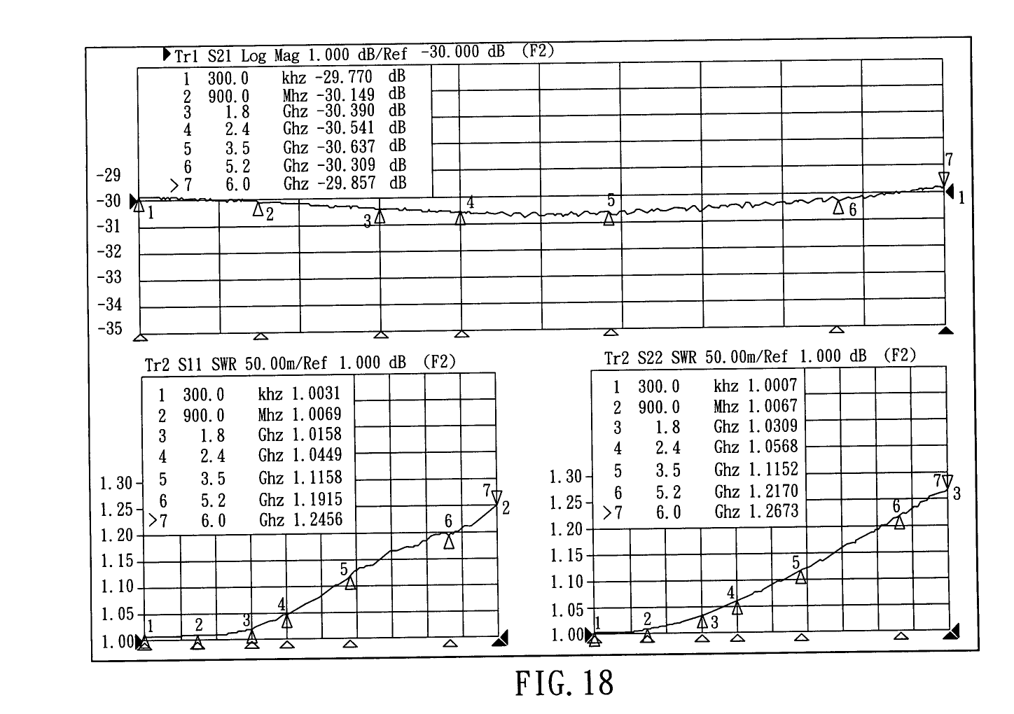

Further, the foregoing three kinds of circuit board modules 5 are installed in the attenuator of a SMA connector, and the testing properties of the attenuators from 300 KHz to 6 GHz are shown in FIGS. 13 to 18. The upper portion of FIGS. 13 to 18 shows a forward gain S21 and a frequency response (in dB); and the lower left corner of the figures shows an input terminal S11 and the frequency response (in unit standing wave ratio); and the lower right corner of the figures shows an output terminal S22 and the frequency response (unit in standing wave ratio). In the testing of the 1 dB attenuator (as shown in FIG. 13), the attenuation approximately ranges from 0.86 dB to 1.38 dB, and the standing wave ratio is lower than 1.15 (approximately equals to the return loss which is superior to 23 dB). In the testing of the 3 dB attenuator (as shown in FIG. 14), the attenuation approximately ranges from 2.74 dB to 3.41 dB, and the standing wave ratio is lower than 1.22 (approximately equals to the return loss which is superior to 20 dB). In the testing of the 6 dB attenuator (as shown in FIG. 15), the attenuation approximately ranges from 5.97 dB to 6.31 dB, and the standing wave ratio is lower than 1.22 (approximately equals to the return loss which is superior to 20 dB). In the testing of the 10 dB attenuator (as shown in FIG. 16), the attenuation approximately ranges from 9.85 dB to 10.16 dB, and the standing wave ratio is lower than 1.10 (approximately equals to the return loss which is superior to 26 dB). In the testing of the 20 dB attenuator (as shown in FIG. 17), the attenuation approximately ranges from 19.99 dB to 20.18 dB, and the standing wave ratio is lower than 1.28 (approximately equals to the return loss which is superior to 18 dB). In the testing of the 30 dB attenuator (as shown in FIG. 18), the attenuation approximately ranges from 29.77 dB to 30.64 dB, and the standing wave ratio is lower than 1.27 (approximately equals to return loss which is superior to 18.5 dB). From FIGS. 13 to 18, it is know that the attenuation of an attenuator approaches the target value for a frequency of the attenuator ranging from a low frequency (300 KHz) to a high frequency (6 GHz).

What is claimed is:

1. An attenuator, comprising:
a main body, having an installing portion concavely disposed between both ends of said main body; and
a circuit board module, having a portion disposed on said installing portion and in contact with said main body.

2. The attenuator of claim 1, further comprising a first connection portion disposed between an end of said main body and said installing portion, and said first connecting portion comprising a first central conductor convexly disposed at a position facing said installing portion, such that said first central conductor is coupled precisely to said circuit board module and disposed at a position proximate to said first connecting portion.

3. The attenuator of claim 2, further comprising a second connecting portion disposed between another end of said main body and said installing portion, and said second connecting portion comprising a second central conductor convexly disposed at a position facing said installing portion, and said second central conductor is coupled precisely to said circuit board module and disposed at a position proximate to said second connecting portion.

4. The attenuator of claim 3, wherein said installing portion at its central position includes a groove, a protruding body disposed separately on both sides of said installing portion, and a shoulder portion disposed on said protruding body and proximate to said groove, and said shoulder portion is in contact separately with both sides of said circuit board module and proximate to the bottom of said circuit board module and the bottom of said circuit board module and proximate to both sides of said circuit board, and the bottom surface of said circuit board module 5 faces the position of said groove and is not in contact with said main body, and said circuit board module is installed and limited onto said installing portion.

5. The attenuator of claim 4, wherein said circuit board module comprises:
a circuit board;
a plurality of first solder pads, intervally disposed on said circuit board facing both sides of said protruding body; and
a plurality of connecting layers, disposed between said first solder pad and said protruding body.

6. The attenuator of claim 5, wherein said first solder pad includes a groove disposed at a corresponding position of said protruding body and a gap formed between said groove and said protruding body, and said connecting layer is disposed in said gap.

7. The attenuator of claim 6, wherein said circuit board includes a plurality of second solder pads disposed between said first solder pads, and having their back facing said groove.

8. The attenuator of claim 7, wherein said second solder pad includes at least one first resistor disposed between said second solder and a first solder pad of at least one side of said circuit board module.

9. The attenuator of claim 8, wherein said second solder pads include at least one second resistance disposed between said solder pads.

10. The attenuator of claim 4, wherein a circuit board of said circuit board module includes three first solder pads separately disposed on both sides of said circuit board.

11. The attenuator of claim 10, wherein said circuit board includes two second solders disposed substantially in a U-shape between said first solder pad and on the opposite side of said groove, and an indent of said second solder pads faces the same side of said circuit board, such that said two first solder pads correspond to said indent of said second solder pads, and said other first solder pad corresponds a gap between said two second solder pads.

12. The attenuator of claim 11, wherein said central conductors are disposed on an opposite side of said second solder pads.

13. The attenuator of claim 12, wherein said circuit board includes a first resistor disposed between said second solder pad and said first solder pad facing an indent of said second solder pad.

14. The attenuator of claim 10, wherein said second solder pad includes a second resistor disposed at a corresponding side of said second solder pad.

15. The attenuator of claim 10, wherein said circuit board includes two T-shaped second solder pads and a rectangular second solder pad disposed between said two T-shaped second solder pad, and said two first solder pads correspond to said T-shaped second solder pads and proximate to said second solder pad, and another first solder pad corresponds to said rectangular second solder pad.

16. The attenuator of claim 15, wherein said first resistor is disposed between a side of said T-shaped second solder pad 56 proximate to said rectangular second solder pad and a side of said first solder pad facing said T-shaped second solder pad and proximate to said rectangular second solder pad.

17. The attenuator of claim 16, wherein said rectangular second solder pad includes a second resistor disposed on a corresponding side of said T-shaped second solder pad.

18. The attenuator of claim 17, wherein said central conductors are disposed precisely on an opposite side of said T-shaped second solder pad.

19. The attenuator of claim 18, wherein said main body includes a casing disposed around the periphery of said installing portion.

20. The attenuator of claim 19, wherein said main body is made of an electrically conducting metal for providing an electrically conducting grounding effect.
